(19) United States
(12) Patent Application Publication
(10) Pub. No.: US 2013/0015569 A1
(43) Pub. Date: Jan. 17, 2013

(54) Semiconductor Device and Method of Forming Substrate With Seated Plane for Mating With Bumped Semiconductor Die

(71) Applicants: Samuel J. Anderson, Tempe, AZ (US); Thomas B. Smiley, Carlsbad, CA (US)

(72) Inventors: Samuel J. Anderson, Tempe, AZ (US); Thomas B. Smiley, Carlsbad, CA (US)

(73) Assignee: GREAT WALL SEMICONDUCTOR CORPORATION, Tempe, AZ (US)

(21) Appl. No.: 13/181,274

(22) Filed: Jul. 12, 2011

(51) Int. Cl. H01L 23/48; H01L 21/58

(52) U.S. Cl. 257/737; 438/121; 257/E23.01; 257/E21.505

(57) ABSTRACT

A semiconductor device has a first insulating layer formed over a substrate. The substrate has a plurality of conductive layers and plurality of second insulating layers formed between the conductive layers. The substrate can be a PCB or interposer. A plurality of openings is formed in the first insulating layer by etching or laser direct ablation. A semiconductor die has a plurality of bumps formed over a surface of the semiconductor die. The pattern of openings coincides with a pattern of the bumps. The die is mounted to the substrate with the bumps disposed within the openings in the first insulating layer. Alternatively, a conductive paste can be disposed within the openings in the first insulating layer. The bumps are reflowed to electrically connect the die to the first substrate. The bumps are substantially contained within the openings of the first insulating layer to reduce bridging between adjacent bumps.

### FIELD OF THE INVENTION

The present invention relates in general to semiconductor devices and, more particularly, to a semiconductor device and method of forming a seated plane over a substrate or PCB with an insulating layer having openings to contain bump material during reflow.

### BACKGROUND OF THE INVENTION

Semiconductor devices are commonly found in modern electronic products. Semiconductor devices vary in the number and density of electrical components. Discrete semiconductor devices generally contain one type of electrical component, e.g., light emitting diode (LED), small signal transistor, resistor, capacitor, inductor, and power metal oxide semiconductor field effect transistor (MOSFET). Integrated semiconductor devices typically contain hundreds to millions of electrical components. Examples of integrated semiconductor devices include microcontrollers, microprocessors, charged-coupled devices (CCDs), solar cells, and digital micro-mirror devices (DMDs).

Semiconductor devices perform a wide range of functions such as signal processing, high-speed calculations, transmitting and receiving electromagnetic signals, controlling electronic devices, transforming sunlight to electricity, and creating visual projections for television displays. Semiconductor devices are found in the fields of entertainment, communications, power conversion, networks, computers, and consumer products. Semiconductor devices are also found in military applications, aviation, automotive, industrial controllers, and office equipment.

Semiconductor devices exploit the electrical properties of semiconductor materials. The atomic structure of semiconductor material allows its electrical conductivity to be manipulated by the application of an electric field or base current or through the process of doping. Doping introduces impurities into the semiconductor material to manipulate and control the conductivity of the semiconductor device.

A semiconductor device contains active and passive electrical structures. Active structures, including bipolar and field effect transistors, control the flow of electrical current. By varying levels of doping and application of an electric field or base current, the transistor either promotes or restricts the flow of electrical current. Passive structures, including resistors, capacitors, and inductors, create a relationship between voltage and current necessary to perform a variety of electrical functions. The passive and active structures are electrically connected to form circuits, which enable the semiconductor device to perform high-speed calculations and other useful functions.

Semiconductor devices are generally manufactured using two complex manufacturing processes, i.e., front-end manufacturing, and back-end manufacturing, each involving potentially hundreds of steps. Front-end manufacturing involves the formation of a plurality of die on the surface of a semiconductor wafer. Each semiconductor die is typically identical and contains circuits formed by electrically connecting active and passive components. Back-end manufacturing involves singulating individual semiconductor die from the finished wafer and packaging the die to provide structural support and environmental isolation. The term “semiconductor die” as used herein refers to both the singular and plural form of the words, and accordingly can refer to both a single semiconductor device and multiple semiconductor devices.

One goal of semiconductor manufacturing is to produce smaller semiconductor devices. Smaller devices typically consume less power, have higher performance, and can be produced more efficiently. In addition, smaller semiconductor devices have a smaller footprint, which is desirable for smaller end products. A smaller die size can be achieved by improvements in the front-end process resulting in die with smaller, higher density active and passive components. Back-end processes may result in semiconductor device packages with a smaller footprint by improvements in electrical interconnection and packaging materials.

FIG. 1 illustrates a conventional semiconductor device 10 with flipchip type semiconductor die 12 having contact pads 14 formed on an active surface 16. A plurality of bumps 18 is formed over contact pads 14. Semiconductor die 12 is mounted to substrate 20 and bumps 18 are reflowed to electrically connect semiconductor die 12 to conductive traces 22 on the substrate. After mounting semiconductor die 12 to substrate 20, an underfill material 24 is deposited between semiconductor die 12 and substrate 20 around bumps 18. An encapsulant or molding compound 26 is deposited over semiconductor die 12 and substrate 20. The temperature and pressure of the reflow process can cause excess bump material to flow outward and contact adjacent conductive traces 22, forming an electric bridge. The formation of the electrical bridge is particularly prevalent in fine pitch interconnect applications. The electrical bridge causes defects, lowers manufacturing yield, and increases cost.

### SUMMARY OF THE INVENTION

A need exists for attaching a semiconductor die to a substrate while reducing electrical bridging between bumps and maintaining robust electrical connections. Accordingly, in one embodiment, the present invention is a method of making a semiconductor device comprising the steps of providing a first substrate, forming a first insulating layer over the first substrate, forming a plurality of openings in the first insulating layer, providing a semiconductor die including a plurality of bumps formed over a surface of the semiconductor die, mounting the semiconductor die to the first substrate with the bumps disposed within the openings in the first insulating layer, and reflowing the bumps to electrically connect the semiconductor die to the first substrate. The bumps are substantially contained within the openings of the first insulating layer to reduce bridging between adjacent bumps.

In another embodiment, the present invention is a method of making a semiconductor device comprising the steps of providing a first substrate including a plurality of first conductive layers between a plurality of insulating layers, forming a plurality of openings in a surface of the first substrate through one of the insulating layers to expose one of the first conductive layers, providing a semiconductor die with a plurality of contact pads, depositing a conductive material within the openings in the surface of the first substrate over the one of the first conductive layers or over the contact pads of the semiconductor die, and mounting the semiconductor die to the first substrate with the conductive material electrically connecting the semiconductor die to the first substrate. The conductive material is substantially contained within the openings in the surface of the first substrate.

In another embodiment, the present invention is a method of making a semiconductor device comprising the steps of providing a first substrate, forming a plurality of openings in a surface of the first substrate, providing a semiconductor die, depositing a conductive material within the openings in the surface of the first substrate or over the semiconductor die, and mounting the semiconductor die to the first substrate with the conductive material electrically connecting the semiconductor die to the first substrate.

In another embodiment, the present invention is a semiconductor device comprising a substrate having a plurality of openings formed in a surface of the substrate. A semiconductor die has a plurality of contact pads formed over a surface of the semiconductor die. A conductive material deposited within the openings in the surface of the first substrate or over the contact pads of the semiconductor die. The semiconductor die is mounted to the substrate with the conductive material electrically connecting the semiconductor die to the substrate.

In another embodiment, the present invention is a method of making a semiconductor device comprising the steps of providing a substrate including a plurality of conductive layers between a plurality of first insulating layers, providing a semiconductor die with a plurality of bumps formed over a surface of the semiconductor die, forming a second insulating layer over the surface of the semiconductor die, and mounting the semiconductor die to the substrate with the bumps electrically connecting the semiconductor die to the conductive layers of the substrate.

### BRIEF DESCRIPTION OF THE DRAWINGS

FIG. 1 shows a conventional semiconductor die mounted to a substrate with bumps;

FIG. 2 illustrates a printed circuit board PCB with different types of packages mounted to its surface;

FIGS. 3a-3c illustrate a semiconductor wafer with a plurality of semiconductor die separated by saw streets;

FIGS. 4a-4j illustrate a process of forming a seated plane over a substrate or PCB with an insulating layer having openings to contain bump material during reflow;

FIGS. 5a-5e illustrate another process of forming a seated plane over a substrate or PCB with an insulating layer having openings to contain bump material during reflow;

FIGS. 6a-6i illustrate a process of forming a seated plane over an interposer with an insulating layer having openings to contain bump material during reflow;

FIGS. 7a-7e illustrate another process of forming a seated plane over an interposer with an insulating layer having openings to contain bump material during reflow; and

FIGS. 8a-8f illustrate a process of forming an insulating layer over a semiconductor die to contain bump material during reflow.

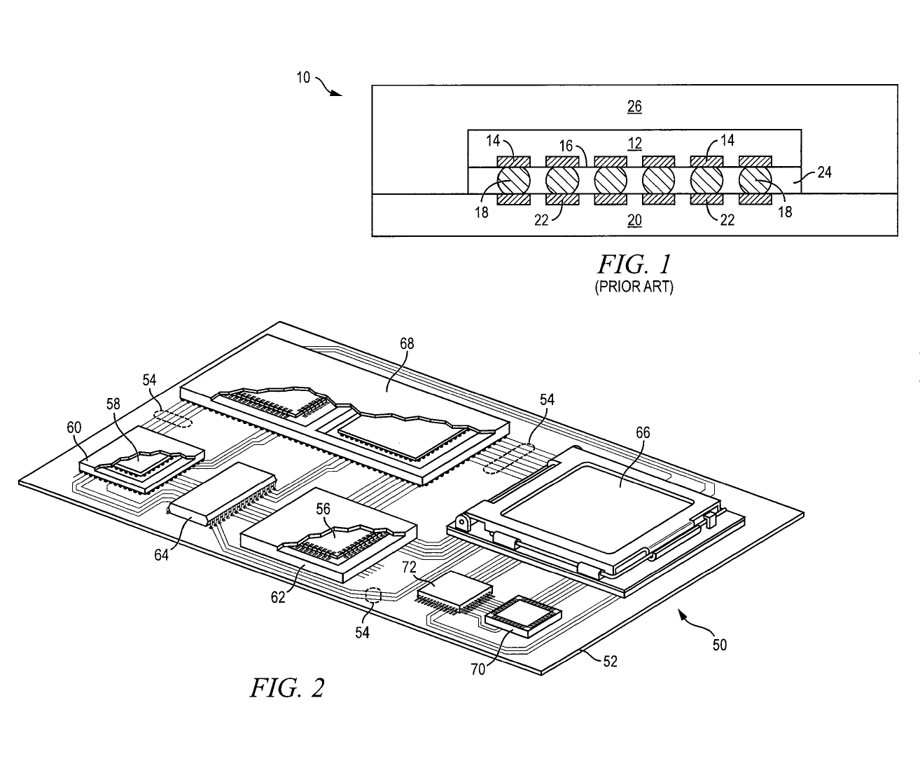

### DETAILED DESCRIPTION OF THE DRAWINGS

The present invention is described in one or more embodiments in the following description with reference to the figures, in which like numerals represent the same or similar elements. While the invention is described in terms of the best mode for achieving the invention's objectives, it will be appreciated by those skilled in the art that it is intended to cover alternatives, modifications, and equivalents as may be included within the spirit and scope of the invention as defined by the appended claims and their equivalents as supported by the following disclosure and drawings.

Semiconductor devices are generally manufactured using two complex manufacturing processes: front-end manufacturing and back-end manufacturing. Front-end manufacturing involves the formation of a plurality of die on the surface of a semiconductor wafer. Each die on the wafer contains active and passive electrical components, which are electrically connected to form functional electrical circuits. Active electrical components, such as transistors and diodes, have the ability to control the flow of electrical current. Passive electrical components, such as capacitors, inductors, resistors, and transformers, create a relationship between voltage and current necessary to perform electrical circuit functions.

Passive and active components are formed over the surface of the semiconductor wafer by a series of process steps including doping, deposition, photolithography, etching, and planarization. Doping introduces impurities into the semiconductor material by techniques such as ion implantation or thermal diffusion. The doping process modifies the electrical conductivity of semiconductor material in active devices, transforming the semiconductor material into an insulator, conductor, or dynamically changing the semiconductor material conductivity in response to an electric field or base current. Transistors contain regions of varying types and degrees of doping arranged as necessary to enable the transistor to promote or restrict the flow of electrical current upon the application of the electric field or base current.

Active and passive components are formed by layers of materials with different electrical properties. The layers can be formed by a variety of deposition techniques determined in part by the type of material being deposited. For example, thin film deposition may involve chemical vapor deposition (CVD), physical vapor deposition (PVD), electrolytic plating, and electroless plating processes. Each layer is generally patterned to form portions of active components, passive components, or electrical connections between components.

The layers can be patterned using photolithography, which involves the deposition of light sensitive material, e.g., photoresist, over the layer to be patterned. A pattern is transferred from a photomask to the photoresist using light. In one embodiment, the portion of the photoresist pattern subjected to light is removed using a solvent, exposing portions of the underlying layer to be patterned. In another embodiment, the portion of the photoresist pattern not subjected to light, the negative photoresist, is removed using a solvent, exposing portions of the underlying layer to be patterned. The remainder of the photoresist is removed, leaving behind a patterned layer. Alternatively, some types of materials are patterned by directly depositing the material into the areas or voids formed by a previous deposition/etch process using techniques such as electroless and electrolytic plating.

Depositing a thin film of material over an existing pattern can exaggerate the underlying pattern and create a non-uniformly flat surface. A uniformly flat surface is required to produce smaller and more densely packed active and passive components. Planarization can be used to remove material from the surface of the wafer and produce a uniformly flat surface. Planarization involves polishing the surface of the wafer with a polishing pad. An abrasive material and corrosive chemical are added to the surface of the wafer during polishing. The combined mechanical action of the abrasive and corrosive action of the chemical removes any irregular topography, resulting in a uniformly flat surface.

Back-end manufacturing refers to cutting or singulating the finished wafer into the individual die and then packaging the die for structural support and environmental isolation. To singulate the die, the wafer is scored and broken along non-functional regions of the wafer called saw streets or scribes. The wafer is singulated using a laser cutting tool or saw blade. After singulation, the individual die are mounted to a package substrate that includes pins or contact pads for interconnection with other system components. Contact pads formed over the semiconductor die are then connected to contact pads within the package. The electrical connections can be made with solder bumps, stud bumps, conductive paste, or wirebonds. An encapsulant or other molding material is deposited over the package to provide physical support and electrical isolation. The finished package is then inserted into an electrical system and the functionality of the semiconductor device is made available to the other system components.

FIG. 2 illustrates electronic device 50 having a chip carrier substrate or PCB 52 with a plurality of semiconductor packages mounted on its surface. Electronic device 50 can have one type of semiconductor package, or multiple types of semiconductor packages, depending on the application. The different types of semiconductor packages are shown in FIG. 2 for purposes of illustration.

Electronic device 50 can be a stand-alone system that uses the semiconductor packages to perform one or more electrical functions. Alternatively, electronic device 50 can be a subcomponent of a larger system. For example, electronic device 50 can be part of a cellular phone, personal digital assistant (PDA), digital video camera (DVC), or other electronic communication device. Alternatively, electronic device 50 can be a graphics card, network interface card, power management, or other signal processing card that can be inserted into a computer. The semiconductor package can include microprocessors, memories, application specific integrated circuits (ASIC), logic circuits, analog circuits, RF circuits, discrete devices, or other semiconductor die or electrical components. Miniaturization and weight reduction are essential for these products to be accepted by the market. The distance between semiconductor devices must be decreased to achieve higher density.

In FIG. 2, PCB 52 provides a general substrate for structural support and electrical interconnect of the semiconductor packages mounted on the PCB. Conductive signal traces 54 are formed over a surface or within layers of PCB 52 using electrolytic plating, electroless plating, screen printing, patterning and etching, or other suitable metal deposition process. Signal traces 54 provide for electrical communication between each of the semiconductor packages, mounted components, and other external system components. Traces 54 also provide power and ground connections to each of the semiconductor packages.

In some embodiments, a semiconductor device has two packaging levels. First level packaging is a technique for mechanically and electrically attaching the semiconductor die to an intermediate carrier. Second level packaging involves mechanically and electrically attaching the intermediate carrier to the PCB. In other embodiments, a semiconductor device may only have the first level packaging where the die is mechanically and electrically mounted directly to the PCB.

For the purpose of illustration, several types of first level packaging, including bond wire package 56 and flipchip 58, are shown on PCB 52. Additionally, several types of second level packaging, including ball grid array (BGA) 60, bump chip carrier (BCC) 62, dual in-line package (DIP) 64, land grid array (LGA) 66, multi-chip module (MCM) 68, quad flat non-leaded package (QFN) 70, and quad flat package 72, are shown mounted on PCB 52. Depending upon the system requirements, any combination of semiconductor packages, configured with any combination of first and second level packaging styles, as well as other electronic components, can be connected to PCB 52. In some embodiments, electronic device 50 includes a single attached semiconductor package, while other embodiments call for multiple interconnected packages. By combining one or more semiconductor packages over a single substrate, manufacturers can incorporate pre-made components into electronic devices and systems. Because the semiconductor packages include sophisticated functionality, electronic devices can be manufactured using cheaper components and a streamlined manufacturing process. The resulting devices are less likely to fail and less expensive to manufacture resulting in a lower cost for consumers.

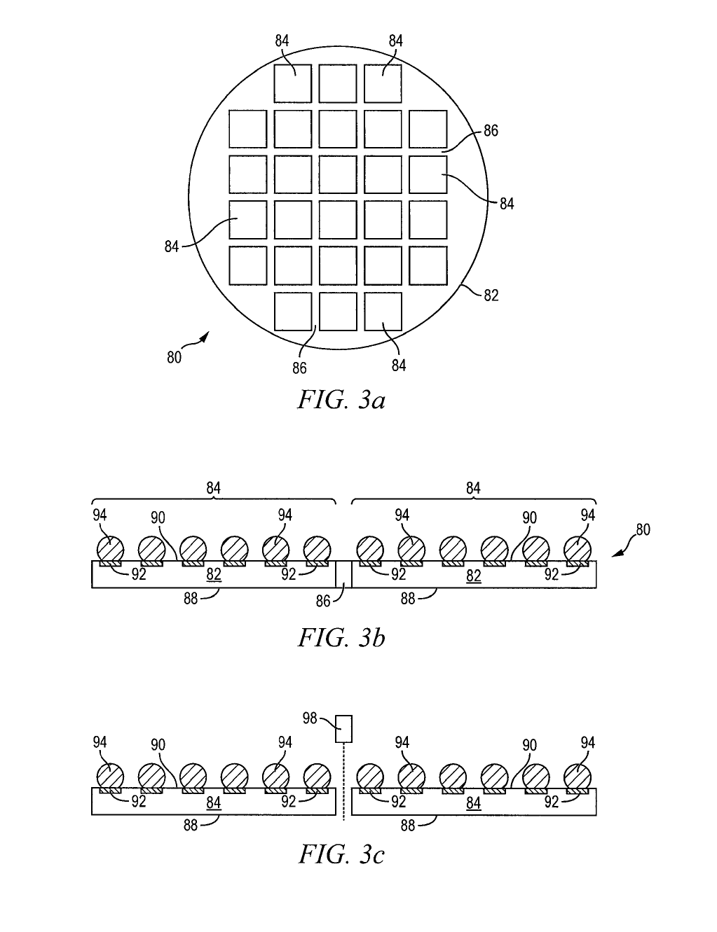

FIG. 3a shows a semiconductor wafer 80 with a base substrate material 82, such as silicon, germanium, gallium arsenide, indium phosphide, or silicon carbide, for structural support. A plurality of semiconductor die or components 84 is formed on wafer 80 separated by a non-active, inter-die wafer area or saw street 86 as described above. Saw street 86 provides cutting areas to singulate semiconductor wafer 80 into individual semiconductor die 84.

FIG. 3b shows a cross-sectional view of a portion of semiconductor wafer 80. Each semiconductor die 84 has a back surface 88 and active surface 90 containing analog or digital circuits implemented as active devices, passive devices, conductive layers, and dielectric layers formed within the die and electrically interconnected according to the electrical design and function of the die. For example, the circuit may include one or more transistors, diodes, and other circuit elements formed within active surface 90 to implement analog circuits or digital circuits, such as digital signal processor (DSP), ASIC, memory, or other signal processing circuit. Semiconductor die 84 may also contain integrated passive devices (IPDs), such as inductors, capacitors, and resistors, for RF signal processing. In one embodiment, semiconductor die 84 is a flipchip type device.

An electrically conductive layer 92 is formed in a pattern over active surface 90 using PVD, CVD, electrolytic plating, electroless plating process, or other suitable metal deposition process. Conductive layer 92 can be one or more layers of Al, Cu, Sn, Ni, Au, Ag, or other suitable electrically conductive material. Conductive layer 92 operates as contact pads electrically connected to the circuits on active surface 90. Contact pads 92 can be disposed side-by-side a first distance from the edge of semiconductor die 84, as shown in FIG. 3b. Alternatively, contact pads 92 can be offset in multiple rows such that a first row of contact pads is disposed a first distance from the edge of the die, and a second row of contact pads alternating with the first row is disposed a second distance from the edge of the die.

An electrically conductive bump material is deposited over contact pads 92 using an evaporation, electrolytic plating, electroless plating, ball drop, or screen printing process. The bump material can be Al, Sn, Ni, Au, Ag, Pb, Bi, Cu, solder, and combinations thereof, with an optional flux solution. For example, the bump material can be eutectic Sn/Pb, high-lead solder, or lead-free solder. The bump material is bonded to contact pads 92 using a suitable attachment or bonding process. In one embodiment, the bump material is reflowed by heating the material above its melting point to form bumps 94 in the same pattern as contact pads 92. In some applications, bumps 94 are reflowed a second time to improve electrical contact to contact pads 92. Bumps 94 can also be compression bonded to contact pads 92. Bumps 94 represent one type of interconnect structure that can be formed over contact pads 92. The interconnect structure can also use stud bump, micro bump, or other electrical interconnect.

In FIG. 3c, semiconductor wafer 80 is singulated through saw street 86 using a saw blade or laser cutting tool 98 into individual semiconductor die 84.

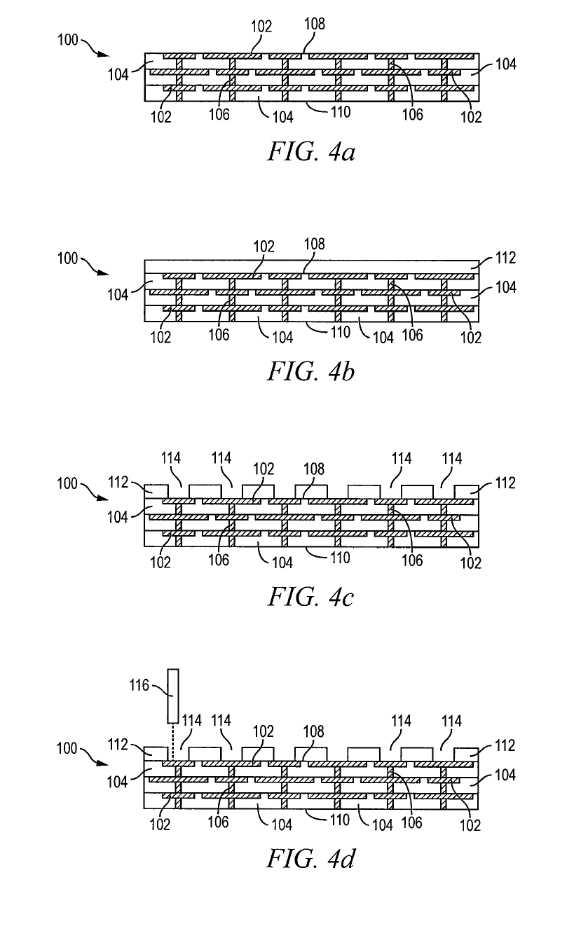

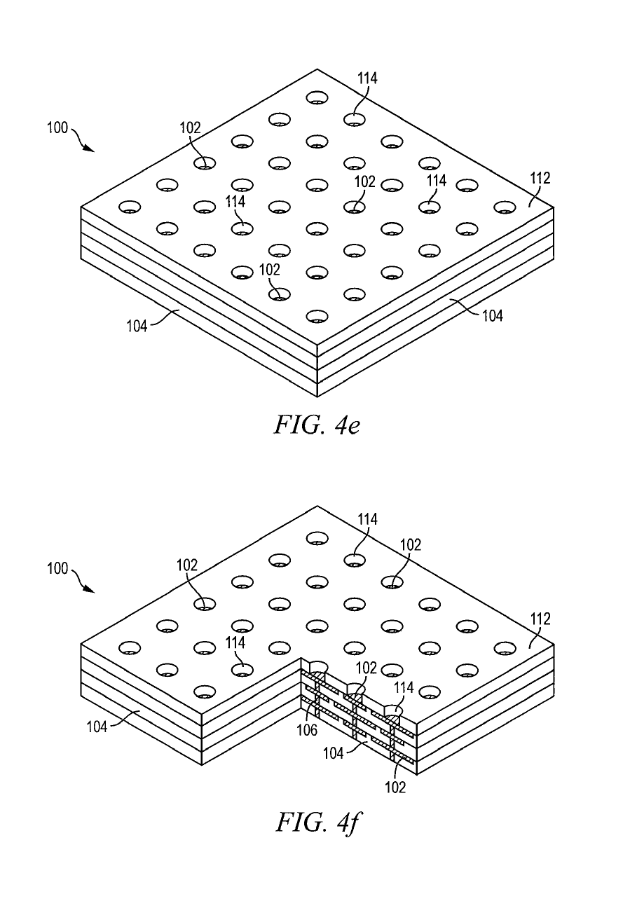

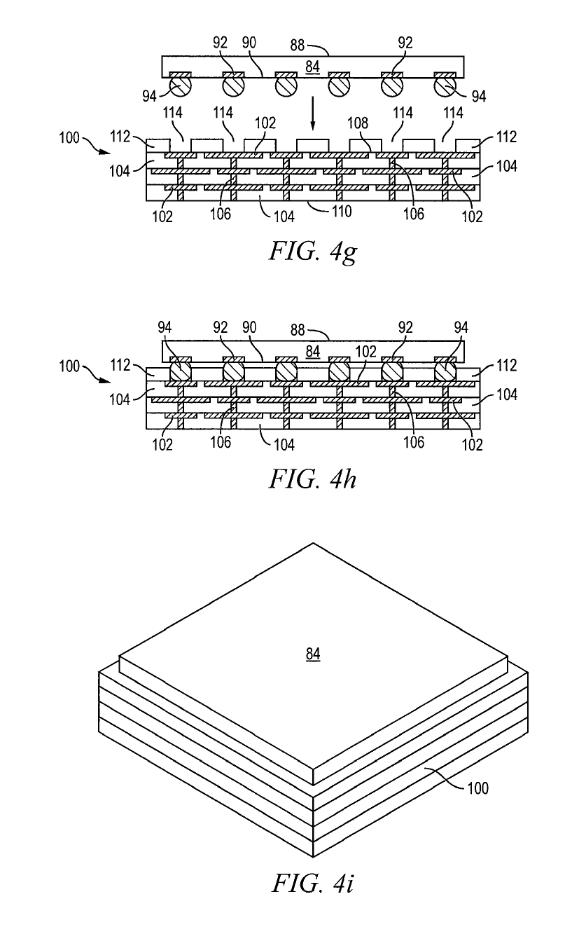

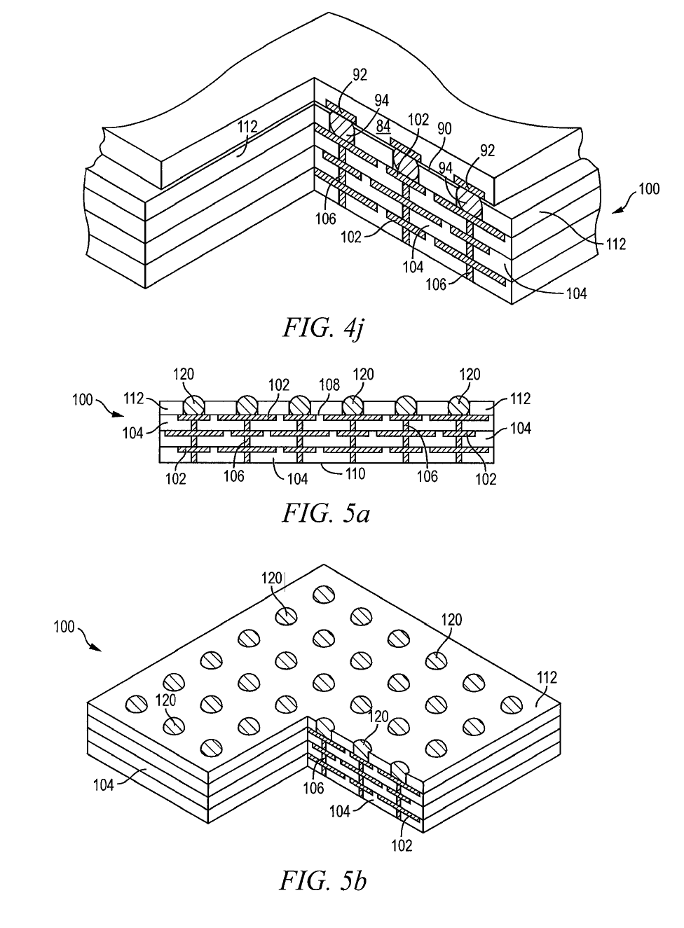

FIGS. 4a-4j illustrate, in relation to FIG. 2, a process of forming a seated plane over a substrate or PCB with an insulating layer having patterned openings to contain bump material during reflow. FIG. 4a shows a portion of substrate or PCB 100 having one or more conductive layers 102 and one or more laminated insulating or dielectric layers 104 formed between conductive layers 102 for electrical isolation. Substrate 100 can have sufficient surface area to contain multiple semiconductor die or packages, similar to FIG. 2. The insulating layers 104 can be one or more laminated layers of polytetrafluoroethylene pre-impregnated (prepreg), FR-4, FR-1, G-10, CEM-1, CEM-3, or organic insulating material, with a combination of phenolic cotton paper, epoxy resin, woven glass, matte glass, polyester, and other reinforcement fibers or fabrics. Conductive layer 102 can be one or more layers of Al, Cu, Sn, Ni, Au, Ag, or other suitable electrically conductive material formed by electrolytic plating or electroless plating for electrical interconnect. In one embodiment, substrate 100 includes four to eight conductive layers 102 and corresponding insulating layers 104.

The layout of conductive layer 102 and insulating layers 104 typically uses silk screen printing, photoengraving, PCB chemical milling, electroless plating, or electroplating process. Substrate 100 may include a plurality of conductive vias 106 formed through the substrate to extend conductive layer 102 between top surface 108 and bottom surface 110 of the substrate. One portion of conductive layer 102 is electrically connected to conductive vias 106. Other portions of conductive layer 102 can be electrically common or electrically isolated depending on the design and function of semiconductor die 84.

In FIG. 4b, an insulating layer 112 is formed over substrate 100 using PVD, CVD, printing, spin coating, spray coating, sintering or thermal oxidation. The insulating layer 112 can contain one or more layers of silicon dioxide (SiO2), silicon nitride (Si3N4), silicon oxynitride (SiON), tantalum pentoxide (Ta2O5), aluminum oxide (Al2O3), or other material having similar insulating and structural properties. Alternatively, insulating layer 112 can be laminated FR4 or other organic or inorganic insulating material with prepreg bonding material. In one embodiment, insulating layer 112 has a sufficient thickness for semiconductor device 84 to be seated on the plane of substrate 200 and make electrical contact with conductive layer 102. A portion of insulating layer 112 is removed by patterning, exposure to UV light, and developing to form patterned openings or cavities 114 and expose conductive layer 102. The openings 114 are formed with a pattern that coincides with the pattern of bumps 94 on semiconductor die 84.

In one embodiment, a portion of insulating layer 112 is removed by subjecting irradiated DFR material to a developer which selectively dissolves non-irradiated portions of the DFR material to create patterned openings 114 in insulating layer 112 disposed over conductive layer 102, while leaving the irradiated portions of the photoresist material intact.

Alternatively, patterned openings 114 are formed by laser direct ablation (LDA) using laser 116 to remove portions of insulating layer 112 to expose conductive layer 112 in applications requiring finer interconnect dimensions, as shown in FIG. 4d. The patterned openings 114 in insulating layer 112 can also be formed by mechanical drilling or laser drilling.

In another embodiment, insulating layer 112 is the top insulating layer 104 on surface 108 of substrate 100. The patterned openings 114 are formed through the top insulating layer of substrate 100 to expose conductive layer 102.

FIG. 4e shows a perspective view of substrate 100 with patterned openings 114 formed within insulating layer 112 to expose conductive layer 102. FIG. 4f shows a cut-away view of substrate 100 with conductive layers 102, insulating layers 104, and conductive vias 106. The patterned openings 114 in insulating layer 112 provide a seated plane for mounting semiconductor die 84 with bumps 94.

In FIG. 4g, semiconductor die 84 from FIGS. 3a-3c is positioned over substrate 100 using a pick and place operation with bumps 94 oriented toward the substrate. In particular, the pattern of bumps 94 on semiconductor die 84 is aligned with the patterned openings 114. The patterned openings 114 aid with the alignment of bumps 94. FIG. 4h shows semiconductor die 84 mounted to substrate 100 with bumps 94 partially contained within patterned openings 114 in insulating layer 112. More specifically, bumps 94 are reflowed to bond with conductive layer 102. The depth of patterned openings 114 and presence of insulating layer 112 restrict the outward flow of bump material during the reflow process to reduce electrical bridging between adjacent bumps. FIG. 4i shows a perspective view of semiconductor die 84 mounted to substrate 100. FIG. 4j shows a cut-away view of semiconductor die 84 mounted to substrate 100 with bumps 94 contained within patterned openings 114 of insulating layer 112.

Semiconductor die 84 is electrically connected through conductive layer 92 and bumps 94 to conductive layer 102 of substrate 100. The patterned openings 114 in insulating layer 112 provide a seated plane for mounting semiconductor die 84 to substrate 100. Bumps 94 are partially contained within patterned openings 114 of insulating layer 112. The depth of patterned openings 114 in insulating layer 112 and presence of insulating layer 112 restrict the outward flow of bump material during the high temperature thermal cycles of the reflow process to reduce electrical bridging between adjacent bumps. The insulating layer 112 with patterned openings 114 supports a robust electrical interconnect between contact pads 92 and conductive layer 102 and a robust mechanical attachment assisting in the prevention of subsequent damage due to dropping or other physical abuse.

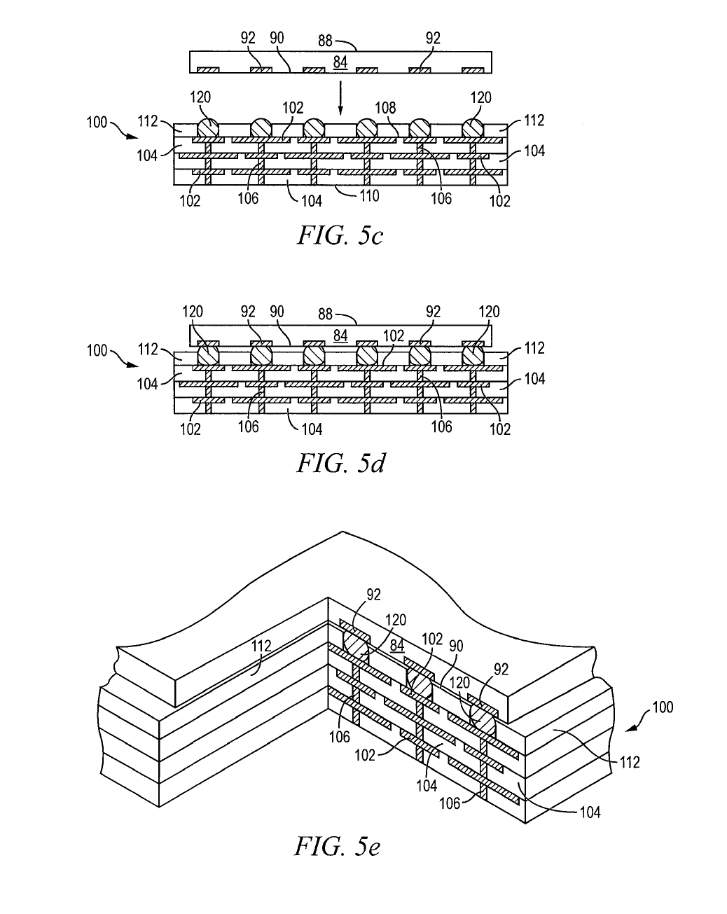

FIG. 5a-5e illustrate another embodiment of forming a seated plane over a substrate or PCB with an insulating layer having patterned openings to contain bump material during reflow. Continuing from FIG. 4f, an electrically conductive bump material 120 is deposited within patterned openings 114 in insulating layer 112 over conductive layer 102 using an evaporation, electrolytic plating, electroless plating, ball drop, stencil, or screen printing process, as shown in FIG. 5a. The bump material can be Al, Sn, Ni, Au, Ag, Pb, Bi, Cu, solder paste, and combinations thereof, with an optional flux solution. For example, the bump material can be eutectic Sn/Pb, high-lead solder, or lead-free solder. Alternatively, a conductive paste can be deposited within patterned openings 114 by screen printing, stencil printing, or direct nozzle injection. FIG. 5b shows a perspective view of substrate 100 with bumps or conductive paste 120 formed within patterned openings 114 of insulating layer 112 over conductive layer 102.

In FIG. 5c, semiconductor die 84 from FIGS. 3a-3c, in this embodiment without bumps 94, is positioned over substrate 100 using a pick and place operation with active surface 90 oriented toward the substrate. In particular, the pattern of contact pads 92 on semiconductor die 84 is aligned with the pattern of openings 114 and bumps 120. The patterned openings 114 aid with the alignment of contact pad 92. FIG. 5d shows semiconductor die 84 mounted to substrate 100 with bumps 120 electrically connected to contact pads 92 and conductive layer 102. More specifically, bumps 120 are reflowed to bond contact pads 92 to conductive layer 102. The depth of patterned openings 114 and presence of insulating layer 112 restrict the outward flow of bump material during the reflow process to reduce electrical bridging between adjacent bumps. FIG. 5e shows a perspective view of semiconductor die 84 mounted to substrate 100 with bumps 120 partially contained within patterned openings 114 of insulating layer 112.

Semiconductor die 84 is electrically connected through conductive layer 92 and bumps 120 to conductive layer 102 of substrate 100. The patterned openings 114 in insulating layer 112 provide a seated plane for mounting semiconductor die 84 to substrate 100. Bumps 120 are partially contained within patterned openings 114 of insulating layer 112. The depth of patterned openings 114 and presence of insulating layer 112 restrict the outward flow of bump material during the high temperature thermal cycles of the reflow process to reduce electrical bridging between adjacent bumps. The insulating layer 112 with patterned openings 114 supports a robust electrical interconnect between contact pads 92 and conductive layer 102, and reduces the risk of mechanical damage due to dropping or other physical abuse, as well as reducing the risk of solder bridging.

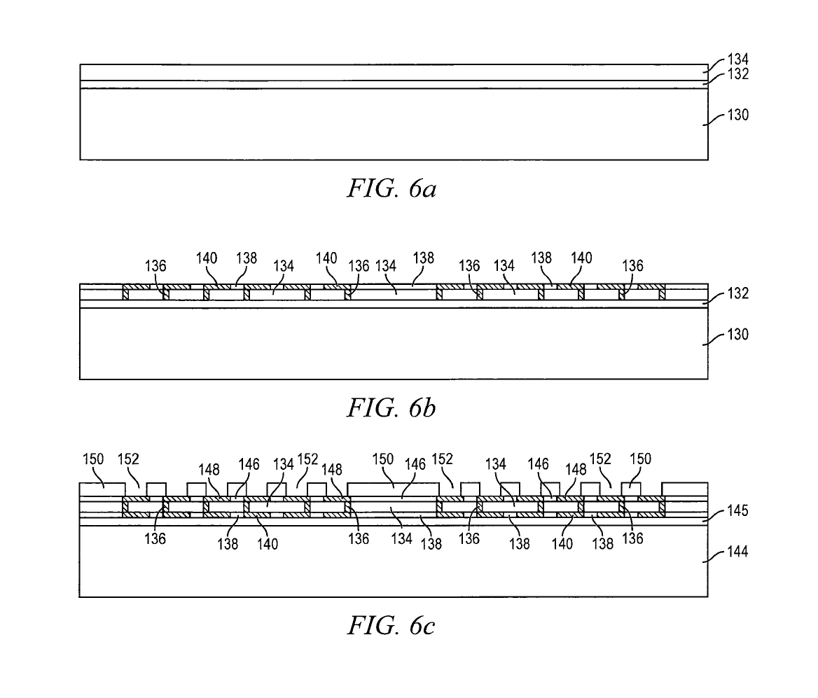

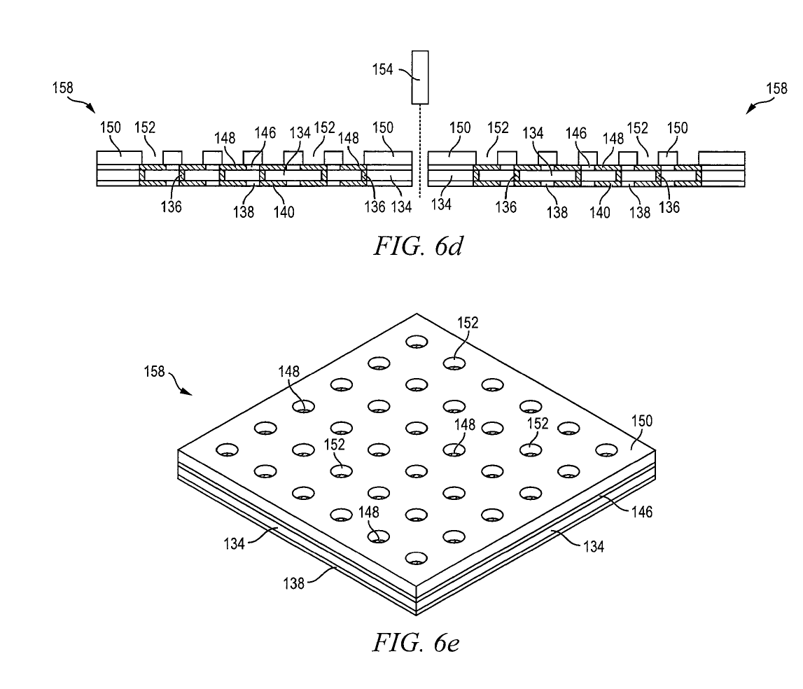

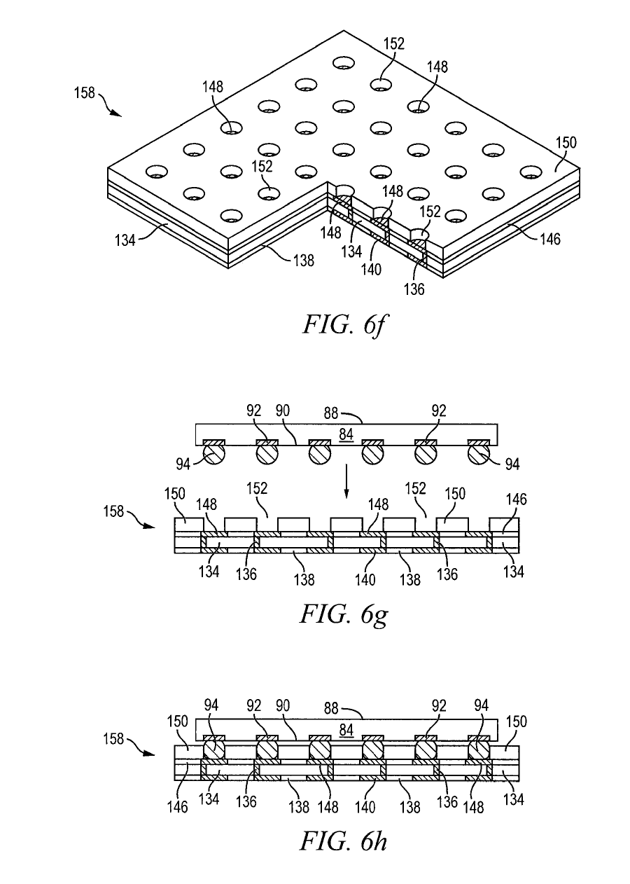

FIGS. 6a-6i illustrate, in relation to FIG. 2, a process of forming a seated plane over an interposer with an insulating layer having patterned openings to contain conductive material. In FIG. 6a, a temporary substrate or carrier 130 contains sacrificial base material such as silicon, polymer, beryllium oxide, or other suitable low-cost, rigid material for structural support. An interface layer or double-sided tape 132 is formed over carrier 130 as a temporary adhesive bonding film or etch-stop layer. A semiconductor wafer or substrate 134 contains a base material, such as silicon, germanium, gallium arsenide, indium phosphide, or silicon carbide, for structural support. As a semiconductor wafer, substrate 134 may contain embedded semiconductor die or passive devices. Substrate 134 can also be a multi-layer laminate, ceramic, or leadframe. Substrate 134 is mounted to interface layer 132 over carrier 130.

In FIG. 6b, a plurality of vias is formed through substrate 134 using laser drilling, mechanical drilling, or deep reactive ion etching (DRIE). The vias are filled with Al, Cu, Sn, Ni, Au, Ag, titanium (Ti), tungsten (W), poly-silicon, or other suitable electrically conductive material using electrolytic plating, electroless plating process, or other suitable metal deposition process to form z-direction vertical interconnect conductive vias 136.

An insulating or passivation layer 138 is formed over a surface of substrate 134 and conductive vias 136 using PVD, CVD, printing, spin coating, spray coating, sintering or thermal oxidation. The insulating layer 138 contains one or more layers of SiO2, Si3N4, SiON, Ta2O5, Al2O3, or other material having similar insulating and structural properties. A portion of insulating layer 138 is removed by an etching process with a photoresist layer (not shown) to expose substrate 134 and conductive vias 136.

An electrically conductive layer or RDL 140 is formed over the exposed substrate 134 and conductive vias 136 using a patterning and metal deposition process such as printing, PVD, CVD, sputtering, electrolytic plating, and electroless plating. Conductive layer 140 can be one or more layers of Al, Cu, Sn, Ni, Au, Ag, or other suitable electrically conductive material. Conductive layer 140 is electrically connected to conductive vias 136. In another embodiment, conductive layer 140 can be formed prior to insulating layer 138.

In FIG. 6c, a temporary substrate or carrier 144 contains sacrificial base material such as silicon, polymer, beryllium oxide, or other suitable low-cost, rigid material for structural support. An interface layer or double-sided tape 145 is formed over carrier 144 as a temporary adhesive bonding film or etch-stop layer. Leading with insulating layer 138 and conductive layer 140, substrate 134 is mounted to interface layer 145 over carrier 144. Carrier 130 and interface layer 132 are removed by chemical etching, mechanical peeling, CMP, mechanical grinding, thermal bake, UV light, laser scanning, or wet stripping to expose a surface of substrate 134 and conductive vias 136 opposite conductive layer 140.

An insulating or passivation layer 146 is formed over a surface of substrate 134 and conductive vias 136, opposite insulating layer 138 and conductive layer 140, using PVD, CVD, printing, spin coating, spray coating, sintering or thermal oxidation. The insulating layer 146 contains one or more layers of SiO2, Si3N4, SiON, Ta2O5, Al2O3, or other material having similar insulating and structural properties. A portion of insulating layer 146 is removed by an etching process with a photoresist layer to expose substrate 134 and conductive vias 136.

An electrically conductive layer or RDL 148 is formed over the exposed surface of substrate 134 and conductive vias 136 using a patterning and metal deposition process such as printing, PVD, CVD, sputtering, electrolytic plating, and electroless plating. Conductive layer 148 can be one or more layers of Al, Cu, Sn, Ni, Au, Ag, or other suitable electrically conductive material. Conductive layer 148 is electrically connected to conductive vias 136.

An insulating or passivation layer 150 is formed over substrate 134, conductive vias 136, insulating layer 146, and conductive layer 148 using PVD, CVD, printing, spin coating, spray coating, sintering or thermal oxidation. The insulating layer 150 contains one or more layers of SiO2, Si3N4, SiON, Ta2O5, Al2O3, or other material having similar insulating and structural properties. A portion of insulating layer 150 is removed by an etching process with a photoresist layer to form patterned openings or cavities 152 and expose conductive layer 148. The openings 152 are formed with a pattern that coincides with the pattern of contact pads 92 on semiconductor die 84. The patterned openings 152 can also be formed by LDA, mechanical drilling, or laser drilling.

In FIG. 6d, carrier 144 and interface layer 145 are removed by chemical etching, mechanical peeling, CMP, mechanical grinding, thermal bake, UV light, laser scanning, or wet stripping to expose insulating layer 138 and conductive layer 140. Substrate 134 is singulated using a saw blade or laser cutting tool 154 into individual interposers 158.

FIG. 6e shows a perspective view of interposer 158 with patterned openings 152 formed in insulating layer 150. FIG. 6f shows a cut-away view of interposer 158 with conductive layers 140 and 148, insulating layers 138, 146, and 150, and conductive vias 136. The patterned openings 152 in insulating layer 150 provide a seated plane for mounting semiconductor die 84 with bumps 94 to interposer 158.

In FIG. 6g, semiconductor die 84 from FIGS. 3a-3c is positioned over interposer 158 using a pick and place operation with bumps 94 oriented toward the interposer. In particular, the pattern of bumps 94 on semiconductor die 84 is aligned with the pattern of openings 152 in insulating layer 150 of interposer 158. The patterned openings 152 aid with the alignment of bumps 94. FIG. 6h shows semiconductor die 84 mounted to interposer 158 with bumps 94 partially contained within patterned openings 152 of insulating layer 150. More specifically, bumps 94 are reflowed to bond with conductive layer 148. The depth of patterned openings 152 and presence of insulating layer 150 restrict the outward flow of bump material during the reflow process to reduce electrical bridging between adjacent bumps. FIG. 6i shows a cut-away view of semiconductor die 84 mounted to interposer 158 with bumps 94 contained within patterned openings 152 of insulating layer 150.

Semiconductor die 84 is electrically connected through conductive layer 92 and bumps 94 to conductive layer 148 of interposer 158. The patterned openings 152 in insulating layer 150 provide a seated plane for mounting semiconductor die 84 to interposer 158. Bumps 94 are partially contained within patterned openings 152 of insulating layer 150. The depth of patterned openings 152 and presence of insulating layer 150 restrict the outward flow of bump material during the high temperature thermal cycles of the reflow process to reduce electrical bridging between adjacent bumps. The insulating layer 150 with patterned openings 152 supports a robust electrical interconnect between contact pads 92 and conductive layer 148, and reduces the risk of mechanical damage due to dropping or other physical abuse, as well as reducing the risk of solder bridging.

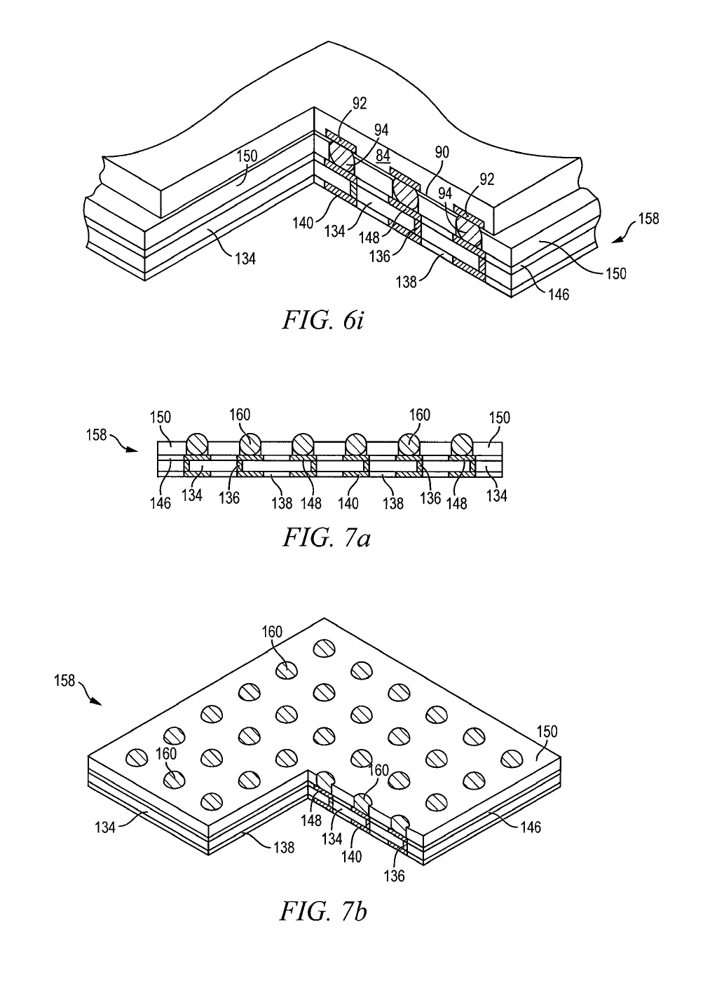

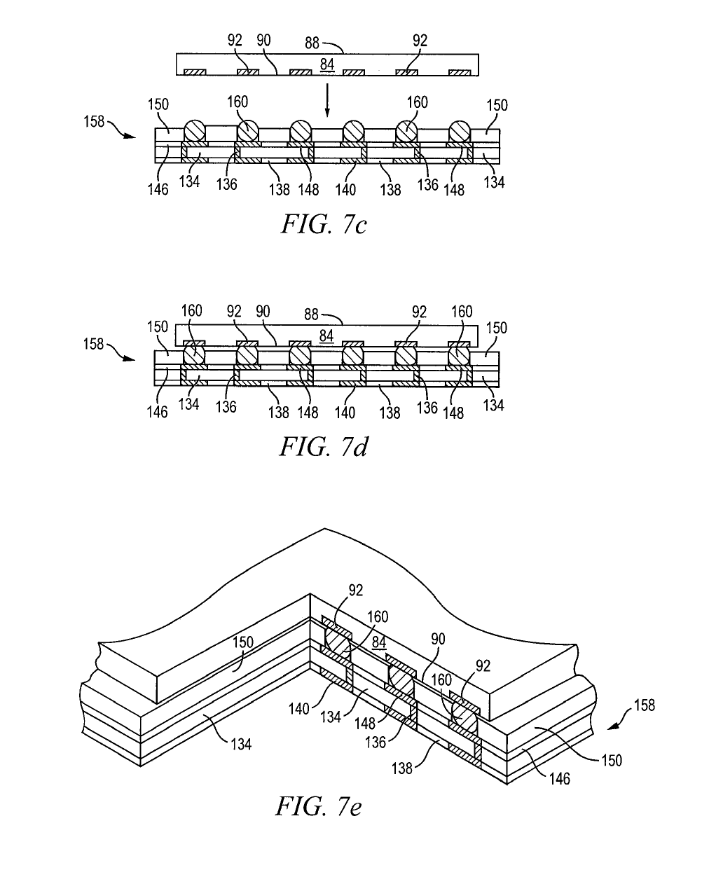

FIG. 7a-7e illustrate another embodiment of forming a seated plane over an interposer with an insulating layer having patterned openings to contain conductive material. Continuing from FIG. 6f, an electrically conductive bump material 160 is deposited within patterned openings 152 in insulating layer 150 over conductive layer 148 using an evaporation, electrolytic plating, electroless plating, ball drop, or screen printing process, as shown in FIG. 5a. The bump material can be Al, Sn, Ni, Au, Ag, Pb, Bi, Cu, solder paste, and combinations thereof, with an optional flux solution. For example, the bump material can be eutectic Sn/Pb, high-lead solder, or lead-free solder. Alternatively, a conductive paste can be deposited within patterned openings 152 by screen printing. FIG. 7b shows a perspective view of bumps or conductive paste 160 formed within patterned openings 152 of insulating layer 150 over conductive layer 148.

In FIG. 7c, semiconductor die 84 from FIGS. 3a-3c, in this embodiment without bumps 94, is positioned over interposer 158 using a pick and place operation with active surface 90 oriented toward the substrate. In particular, the pattern of contact pads 92 on semiconductor die 84 is aligned with the pattern of openings 152 in insulating layer 150 of interposer 158. FIG. 7d shows semiconductor die 84 mounted to interposer 158 with bumps 160 electrically connected to contact pads 92 and conductive layer 148. More specifically, bumps 160 are reflowed to bond contact pads 92 to conductive layer 148. The depth of patterned openings 152 and presence of insulating layer 150 restrict the outward flow of bump material during the reflow process to reduce electrical bridging between adjacent bumps. FIG. 7e shows a perspective view of semiconductor die 84 mounted to interposer 158 with bumps 160 partially contained within patterned openings 152 of insulating layer 150.

Semiconductor die 84 is electrically connected through conductive layer 92 and bumps 160 to conductive layer 148 of interposer 158. The patterned openings 152 in insulating layer 150 provide a seated plane for mounting semiconductor die 84 to interposer 158. Bumps 160 are partially contained within patterned openings 152 of insulating layer 150. The depth of patterned openings 152 and presence of insulating layer 150 restrict the outward flow of bump material during the high temperature thermal cycles of the reflow process to reduce electrical bridging between adjacent bumps. The insulating layer 150 with patterned openings 152 supports a robust electrical interconnect between contact pads 92 and conductive layer 148.

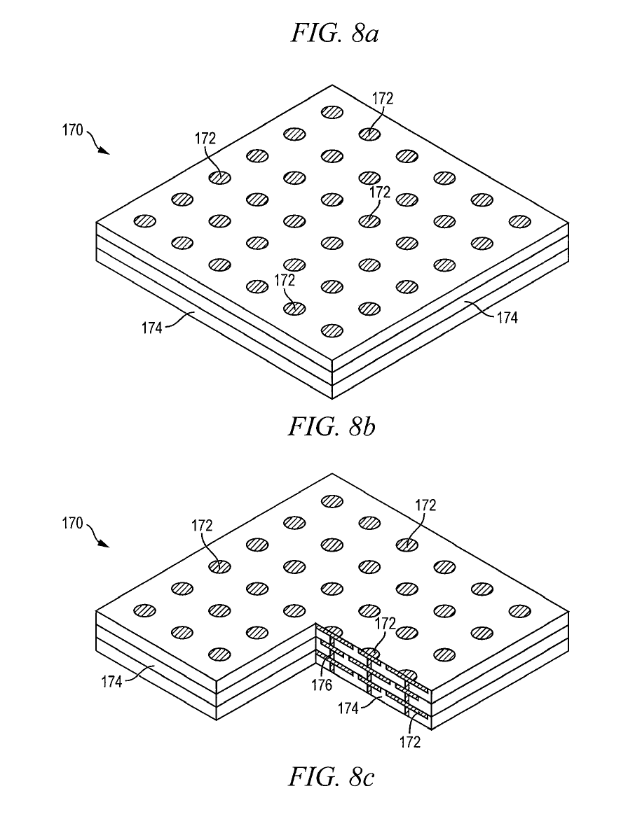

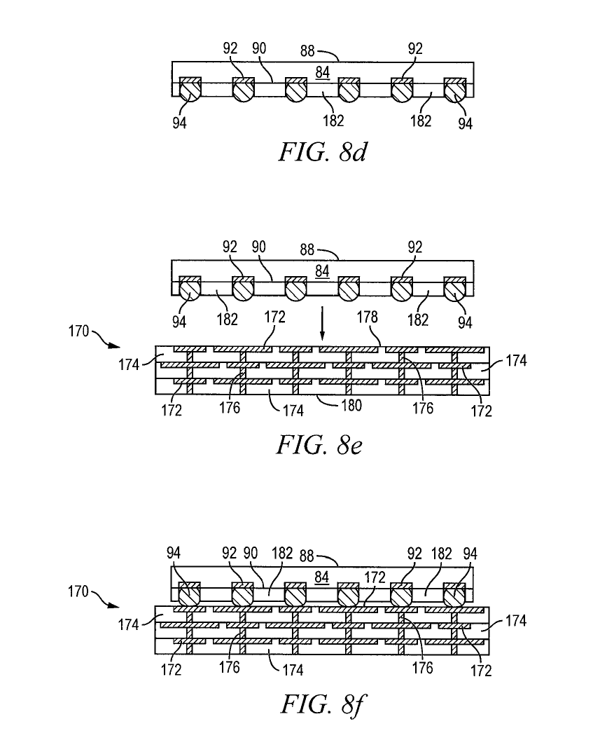

FIGS. 8a-8f illustrate, in relation to FIG. 2, a process of forming an insulating layer over semiconductor die 84 to contain bump material during reflow. FIG. 8a shows a substrate or PCB 170 having one or more conductive layers 172 formed on laminated insulating or dielectric layers 174. The insulating layers 174 can be one or more laminated layers of polytetrafluoroethylene prepreg, FR-4, FR-1, G-10, CEM-1, or CEM-3 with a combination of phenolic cotton paper, epoxy resin, woven glass, matte glass, polyester, and other reinforcement fibers or fabrics. Conductive layer 172 can be one or more layers of Al, Cu, Sn, Ni, Au, Ag, or other suitable electrically conductive material formed by electrolytic plating or electroless plating for electrical interconnect. In one embodiment, substrate 170 includes four to eight conductive layers 172 and insulating layers 174.

The layout of conductive layer 172 and insulating layers 174 typically uses silk screen printing, photoengraving, PCB milling, electroless plating, or electroplating process. Substrate 170 may include a plurality of conductive vias 176 formed through the substrate to extend conductive layer 172 between top surface 178 and bottom surface 180 of the substrate. One portion of conductive layer 172 is electrically connected to conductive vias 176. Other portions of conductive layer 172 can be electrically common or electrically isolated depending on the design and function of semiconductor die 84.

FIG. 8b shows a perspective view of substrate 170 with exposed conductive layer 172. FIG. 8c shows a cut-away view of substrate 170 with conductive layers 172, insulating layers 174, and conductive vias 106.

In FIG. 8d, an insulating layer 182 is formed over active surface 90 of semiconductor die 84, around bumps 94, using PVD, CVD, printing, spin coating, spray coating, sintering or thermal oxidation. The insulating layer 182 can contain one or more layers of SiO2, Si3N4, SiON, Ta2O5, Al2O3, or other material having similar insulating and structural properties.

In FIG. 8e, semiconductor die 84 from FIGS. 3a-3c is positioned over substrate 170 using a pick and place operation with bumps 94 oriented toward the substrate. In particular, bumps 94 are aligned with conductive layer 172. FIG. 8f shows semiconductor die 84 mounted to substrate 170 with bumps 94 are reflowed to bond with conductive layer 172. The insulating layer 182 restricts the outward flow of bump material during the reflow process to reduce electrical bridging between adjacent bumps.

Semiconductor die 84 is electrically connected through conductive layer 92 and bumps 94 to conductive layer 172 of substrate 170. Bumps 94 are partially contained within insulating layer 182. The insulating layer 182 restricts the outward flow of bump material during the high temperature thermal cycles of the reflow process to reduce electrical bridging between adjacent bumps. The insulating layer 182 supports a robust electrical interconnect between contact pads 92 and conductive layer 172.

While one or more embodiments of the present invention have been illustrated in detail, the skilled artisan will appreciate that modifications and adaptations to those embodiments may be made without departing from the scope of the present invention as set forth in the following claims.

1. A method of making a semiconductor device, comprising:
providing a first substrate;
forming a first insulating layer over the first substrate;
forming a plurality of openings in the first insulating layer;
providing a semiconductor die including a plurality of bumps formed over a surface of the semiconductor die;
mounting the semiconductor die to the first substrate with the bumps disposed within the openings in the first insulating layer; and
reflowing the bumps to electrically connect the semiconductor die to the first substrate, wherein the bumps are substantially contained within the openings of the first insulating layer to reduce bridging between adjacent bumps.

2. The method of claim 1, wherein providing the first substrate includes:
forming a plurality of first conductive layers within the first substrate; and
forming a plurality of second insulating layers between the first conductive layers.

3. The method of claim 2, wherein forming the plurality of openings in the first insulating layer includes removing a portion of the first insulating layer over the first conductive layers of the first substrate by etching or laser direct ablation.

4. The method of claim 1, wherein the first substrate includes a printed circuit board or interposer.

5. The method of claim 4, wherein the interposer includes:
providing a second substrate;
forming a plurality of conductive vias through the second substrate;
forming a second conductive layer over a first surface of the second substrate; and
forming a third conductive layer over a second surface of the second substrate opposite the first surface of the second substrate.

6. The method of claim 1, wherein a pattern of the plurality of openings coincide with a pattern of the bumps.

7. A method of making a semiconductor device, comprising:
providing a first substrate including a plurality of first conductive layers between a plurality of insulating layers;
forming a plurality of openings in a surface of the first substrate through one of the insulating layers to expose one of the first conductive layers;
providing a semiconductor die with a plurality of contact pads;
depositing a conductive material within the openings in the surface of the first substrate over the one of the first conductive layers or over the contact pads of the semiconductor die; and
mounting the semiconductor die to the first substrate with the conductive material electrically connecting the semiconductor die to the first substrate, wherein the conductive material is substantially contained within the openings in the surface of the first substrate.

8. The method of claim 7, wherein the first substrate includes a printed circuit board or interposer.

9. The method of claim 8, wherein the interposer includes:
providing a second substrate;
forming a plurality of conductive vias through the second substrate;
forming a second conductive layer over a first surface of the second substrate; and
forming a third conductive layer over a second surface of the second substrate opposite the first surface of the second substrate.

10. The method of claim 7, wherein forming the plurality of openings in the surface of the first substrate includes removing a portion of the one of the insulating layers over the first conductive layers of the substrate by etching or laser direct ablation.

11. The method of claim 7, wherein the conductive material includes a conductive paste or bump material.

12. A method of making a semiconductor device, comprising:
providing a first substrate;
forming a plurality of openings in a surface of the first substrate;
providing a semiconductor die;
depositing a conductive material within the openings in the surface of the first substrate or over the semiconductor die; and
mounting the semiconductor die to the first substrate with the conductive material electrically connecting the semiconductor die to the first substrate.

13. The method of claim 12, wherein the first substrate includes a printed circuit board or interposer.

14. The method of claim 13, wherein the interposer includes:
providing a second substrate;
forming a plurality of conductive vias through the second substrate;
forming a first conductive layer over a first surface of the second substrate; and
forming a second conductive layer over a second surface of the second substrate opposite the first surface of the second substrate.

15. The method of claim 12, wherein providing the first substrate includes:
forming a plurality of conductive layers within the first substrate; and
forming a plurality of insulating layers between the conductive layers.

16. The method of claim 15, wherein forming the plurality of openings in the surface of the first substrate includes removing a portion of the one of the insulating layers over the conductive layers of the substrate by etching or laser direct ablation.

17. The method of claim 12, wherein the conductive material includes a conductive paste or bump material.

18. A semiconductor device, comprising:
a substrate having a plurality of openings formed in a surface of the substrate;
a semiconductor die having a plurality of contact pads formed over a surface of the semiconductor die; and
a conductive material deposited within the openings in the surface of the first substrate or over the contact pads of the semiconductor die, wherein the semiconductor die is mounted to the substrate with the conductive material electrically connecting the semiconductor die to the substrate.

19. The semiconductor device of claim 18, wherein the substrate includes a printed circuit board or interposer.

20. The semiconductor device of claim 18, wherein the first substrate includes:
a plurality of conductive layers formed within the substrate; and
a plurality of insulating layers formed between the conductive layers.

21. The semiconductor device of claim 18, wherein the conductive material includes a conductive paste or bump material.

22. A method of making a semiconductor device, comprising:
providing a substrate including a plurality of conductive layers between a plurality of first insulating layers;
providing a semiconductor die with a plurality of bumps formed over a surface of the semiconductor die;
forming a second insulating layer over the surface of the semiconductor die; and
mounting the semiconductor die to the substrate with the bumps electrically connecting the semiconductor die to the conductive layers of the substrate.

23. The method of claim 22, further including depositing a conductive material within openings in a surface of the second insulating layer.

24. The method of claim 22, wherein the substrate includes a printed circuit board or interposer.

25. The method of claim 22, wherein providing the substrate includes:
forming a plurality of conductive layers within the substrate; and
forming a plurality of insulating layers between the conductive layers.
